(19) United States
(12) Patent Application Publication
(10) Pub. No.: US 2025/0285992 A1
(43) Pub. Date: Sep. 11, 2025

(54) METHODS AND STRUCTURES FOR REDUCING WARPAGE

(71) Applicant: Applied Materials, Inc., Santa Clara, CA (US)

(72) Inventors: Siddarth Krishnan, San Jose, CA (US); Michael Chudzik, Mountain View, CA (US)

(73) Assignee: Applied Materials, Inc., Santa Clara, CA (US)

(21) Appl. No.: 18/596,272

(22) Filed: Mar. 5, 2024

(51) Int. Cl. H01L 23/00; H01L 21/02; H01L 21/311

(52) U.S. Cl. CPC H01L 23/562; H01L 21/02354; H01L 21/31144; H01L 24/08; H01L 24/80; H01L 2224/08145; H01L 2224/80895; H01L 2224/80896

(57) ABSTRACT

A semiconductor structure including a dielectric film wherein stress has been inducted into one or more stressed portions of the dielectric film to create one or more stress zones. The stress zones correspond to locations of warpage in the semiconductor structure and reduce warpage. In some examples, the stress zones can be created by exposing portions of the dielectric film to different amounts of heat. In some examples, the stress zones can be created by one or more recesses in the dielectric film.

### TECHNICAL FIELD

The present technology relates to semiconductor systems, processes, and equipment. More specifically, the present technology relates to processes and semiconductor devices for hybrid bonding.

### BACKGROUND

Hybrid bonding (which can also be referred to as heterogeneous integration) is a semiconductor fabrication technique that allows for increased miniaturization of three-dimensional semiconductor device fabrication processes related to advanced node technologies requiring heterogenous integration of surfaces. Hybrid bonding involves the creation of strong bonds between surfaces of dies, wafers, and/or substrates without the need for adhesives or interconnect materials. However, heterogenous integration techniques can be limited when integrating at least one large surface to another surface because either surface can have warpage. The warpage can be caused by tiny differences in stress and/or pressure across a surface. The warpage can prevent the proper creation of the bonds between surfaces and between interconnect materials. Standard hybrid bonding techniques and systems may be incapable of limiting warpage.

Thus, there is a need for improved systems and methods for hybrid bonding that can reduce stress, pressure, and/or warpage in or of a surface and improve the bonding between two surfaces. These and other needs are addressed by the present technology.

### SUMMARY

In some embodiments, semiconductor structure for hybrid bonding, may include a first structure that may include a bonding surface and a surface opposite of the bonding surface. The bonding surface may include conductive areas and dielectric areas. The semiconductor structure may also include a film overlaying the first structure on the surface of the first structure that is opposite of the bonding surface. The film may include one or more stressed portions that compensate for warpage in the first structure.

In some embodiments, a method of forming a semiconductor structure may include forming a first structure that may include a bonding surface and a surface opposite of the bonding surface. The bonding surface may include conductive areas and dielectric areas. The method may also include forming a film overlaying the first structure on the surface of the first structure that is opposite of the bonding surface. The film may include one or more stressed portions that compensate for warpage in the first structure.

In some embodiments, a method may include obtaining data for a semiconductor structure that is indicative of warpage locations; and causing stress to be induced into one or more portions of a film on the semiconductor structure to create one or more stressed portions that compensate for the warpage locations.

In some embodiments, a semiconductor structure for hybrid bonding may include a first structure, which may include a first metal layer overlaying a first substrate; a first dielectric layer overlaying the first metal layer and defining a one or more features recessed in the first dielectric layer; and a first copper-containing material deposited within the one or more features; and a dielectric film overlaying the first structure, wherein stress has been induced into one or more stressed portions of the dielectric film creating one or more stress zones in the first structure, wherein the one or more stress zones correspond to locations of warpage in the first structure.

In some embodiments, a method of forming a semiconductor structure may include forming a first structure, wherein forming the first structure may include forming a first metal layer over a first substrate; forming a first dielectric layer over the first metal layer; etching a trench in the first dielectric layer, wherein the trench extends from a top surface of the first dielectric layer down to at least a top surface of the first metal layer; and filling the trench with a first copper-containing material; and forming a dielectric film over the first substrate; and inducing stress into one or more stressed portions in the dielectric film creating one or more stress zones in the first structure, wherein the one or more stress zones correspond to locations of warpage in the first structure.

In some embodiments, one or more non-transitory computer-readable media can include instructions that, when executed by one or more processors, cause the one or more processors to perform operations which may include determining first locations of warpage in a semiconductor wafer by performing a metrology test on the semiconductor wafer; determining second locations to induce stress into one or more stressed portions of a dielectric film overlaying the semiconductor wafer to create one or more stress zones in the semiconductor wafer, wherein the one or more stress zones correspond to the first locations of warpage; forming the dielectric film over the semiconductor wafer; and forming the dielectric film over the semiconductor wafer.

In any embodiments, any and all of the following features may be implemented in any combination and without limitation. The one or more stressed portions can include one or more recesses in the dielectric film. The one or more stressed portions can include a first portion exposed to a first amount of heat creating a first stress zone in the first structure, and a second portion exposed to a second amount of heat different than the first amount of heat. The first portion and the second portion can correspond to a first location and second location, respectively, of warpage in the first structure. The dielectric film can overlay the first substrate. The semiconductor structure can further include a second structure, which may include a second metal layer overlaying a second substrate; a second dielectric layer overlaying the second metal layer and defining a second set of one or more features recessed in the second dielectric layer; and a second copper-containing material deposited within the second set of one or more features. The first dielectric layer of the first structure can be hybrid bonded to the second dielectric layer of the second structure. The first copper-containing material of the first structure can contact the second copper-containing material of the second structure. The dielectric film can overlay the dielectric layer. The method of forming the semiconductor structure can also include forming a photoresist layer over the dielectric film. Inducing stress into the one or more stressed portions can include determining areas for each of one or more recesses to place in the stressed portions of the dielectric film. Inducing stress into the one or more stressed portions can include applying photolithography to the photoresist layer based on the areas for each of the one or more recesses to form a second set of one or more recesses in the photoresist layer, wherein the second set of one or more recesses corresponds to the one or more recesses. Inducing stress into the one or more stressed portions can include applying an etchant to the photoresist layer and the dielectric film to form the one or more recesses in the dielectric film. Inducing stress into the one or more stressed portions can include applying a first amount of heat to a first portion of the dielectric film to form a first stress zone in the first structure. Inducing stress into the one or more stressed portions can include applying a second amount of heat to a second portion of the dielectric film, wherein the first amount of heat is different from the second amount of heat to form a second stress zone in the first structure. The first portion and the second portion can correspond to a first location and second location, respectively, of warpage in the first structure. A laser can be used to apply the first amount of heat and the second amount of heat. The dielectric film overlays the first dielectric layer. The method of forming the semiconductor structure can also include removing the dielectric film from overlaying the first dielectric layer. The method of forming the semiconductor structure can also include removing the dielectric film from overlaying the first substrate. The method of forming the semiconductor structure can also include removing the dielectric film from overlaying the first substrate after bonding the first structure to the second structure. The method of forming the semiconductor structure can also include determining one or more sizes and one or more shapes for the one or more stressed portions. The method of forming the semiconductor structure can also include determining a material for the dielectric film. The method of forming the semiconductor structure can also include determining a film thickness for the dielectric film.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers that may be included or configured according to some embodiments.

FIGS. 2A-2B illustrate exemplary diagrams of warpage according to some embodiments.

FIG. 3 illustrates operations in a semiconductor processing method according to some embodiments.

FIGS. 4A-4H illustrate exemplary schematic cross-sectional views of structures in which material layers are included and processed according to some embodiments.

FIG. 5 illustrates operations in a semiconductor processing method according to some embodiments.

FIGS. 6A-6C illustrate exemplary schematic cross-sectional views of structures in which material layers are included and processed according to some embodiments.

FIG. 7 illustrates an exemplary computer system, in which various embodiments may be implemented.

### DETAILED DESCRIPTION

Inducing stress into stressed portions of a dielectric film applied to a first structure can reduce warpage in the first structure (and the semiconductor wafer containing the first structure) to improve the formation of semiconductor devices that are composed of hybrid bonded structures. In one example of inducing stress into the stressed portion of the dielectric film to reduce warpage, recesses can be formed in the dielectric film via photoresist and photolithography. In another example varying amounts of heat can be applied to the different portions of the dielectric film to induce stress into the stressed portion of the dielectric film to reduce warpage. For example, a laser or heating lamps can apply different amounts of heat to the different portions of the dielectric film.

While conventional hybrid bonding systems may be used to create semiconductor structures (for example three-dimensional structures such as a NAND array) on semiconductor wafers and/or chips, warpage across the wafer may reduce yields as interconnects between semiconductor structures may not properly form. For example, warpage in a wafer may be multi-dimensional and localized which may create unique waves and troughs in the surface of the wafer. When a wafer is bonded to another wafer, the warpage may cause portions of the wafers to be farther apart such that the hybrid bonding process does not properly occur between those portions of the wafers. The present technology overcomes these issues associated with conventional hybrid bonding systems by creating stress zones in the wafers (and corresponding semiconductor structures) via stressing an applied dielectric film. By applying and stressing a dielectric film, the localized warpage in a wafer can be reduced and/or eliminated.

As an overview, hybrid bonding is a semiconductor fabrication technique that combines the advantages of both direct bonding and traditional bonding methods. It enables the integration of dissimilar materials at a molecular level, facilitating the development of advanced semiconductor devices with improved performance, functionality, and miniaturization that may not require the use of metal interconnects. Hybrid bonding is particularly helpful for three-dimensional semiconductor device fabrication.

When a system consisting of two wafers (dies, substrates, and the like can also be used) are being bonded together via hybrid bonding, the top surface dielectrics of the wafers are first treated to create a reactive layer via surface activation. Then the top surface dielectrics can be contacted to each other to bond, for example by spontaneous hydrophilic oxide-oxide bonding. Once the top surface dielectric have been bonded, the metal pads of each wafer will be separated by a dishing gap. The system can then be annealed such that the metal pads of each wafer will thermally expand and connect while the top surface dielectrics will remain approximately the same size by comparison to the metal. Once the annealing is complete, the wafers have been bonded via hybrid bonding.

Although the remaining disclosure will routinely identify specific hybrid bonding processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

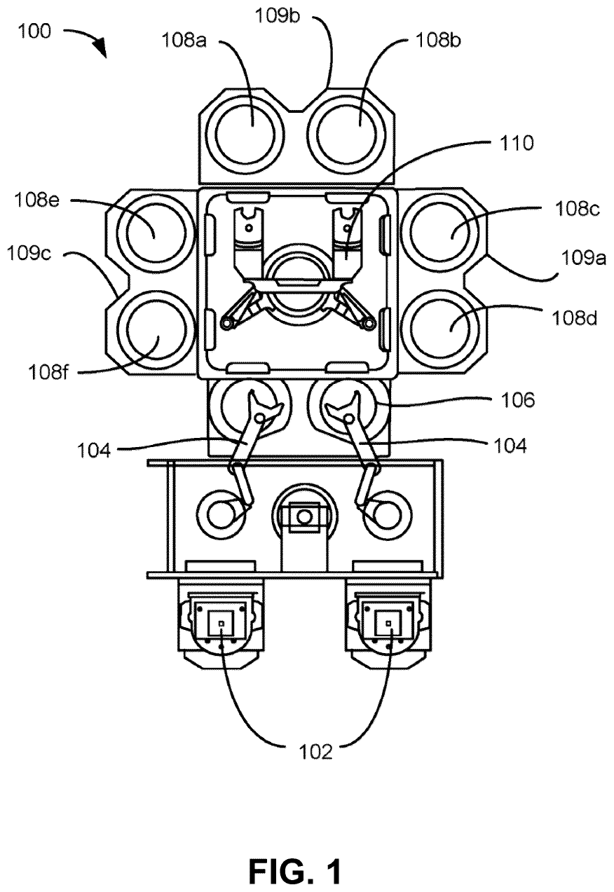

FIG. 1 illustrates a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

System 100, or more specifically chambers incorporated into system 100 or other processing systems, may be used to produce structures according to some embodiments of the present technology.

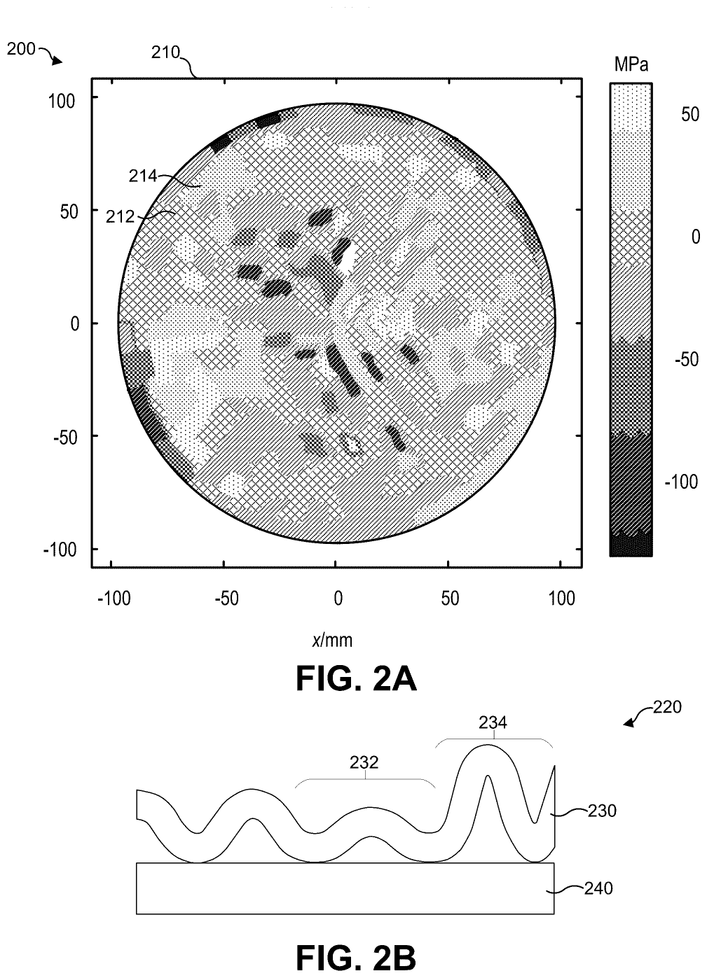

FIG. 2A illustrates a diagram 200 of a top view of a semiconductor wafer that has localized warpage. The graph 210 is an example scan and/or reading of a semiconductor wafer that indicates the stresses in the semiconductor wafer. For example, portion 212 has a different level of stress than portion 214. Graph 210 can be an example metrology reading or scan that detects pressure in the semiconductor wafer. Pressure in the wafer can be indicative of stresses in the wafer. Similarly, pressure in the wafer can be indicative of warpage in the wafer. Other types of metrology readings can be used to detect warpage and/or stresses in a wafer. For example, warpage can be detected by measuring the displacement of portions of the surface of the wafer compared to a normal. FIG. 2B illustrates a side view of warpage a wafer 230 that has local warpage as compared to a wafer 240 with minimal warpage. As shown at portion 232 and portion 234, local warpage can vary both in height and length along the wafer. When attempting to hybrid bond two wafers (or any combination of two wafers, chips, or dies/dice), warpage can cause metal in the wafers to be too far apart during the annealing process of hybrid bonding.

When the metal in the wafers is too far apart, interconnects may be prevented from being formed between the two wafers. This can lead to structures and/or chips that are not functional because the interconnects between structures on the two wafers do not properly connect.

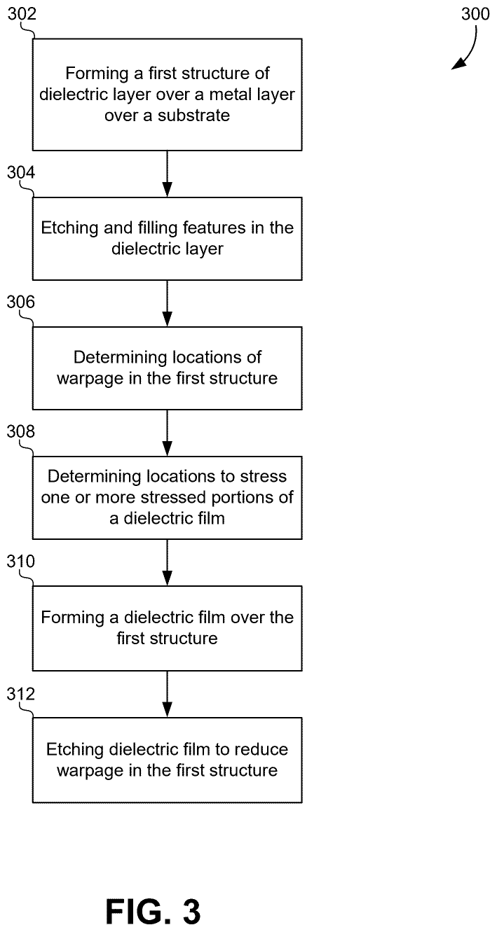

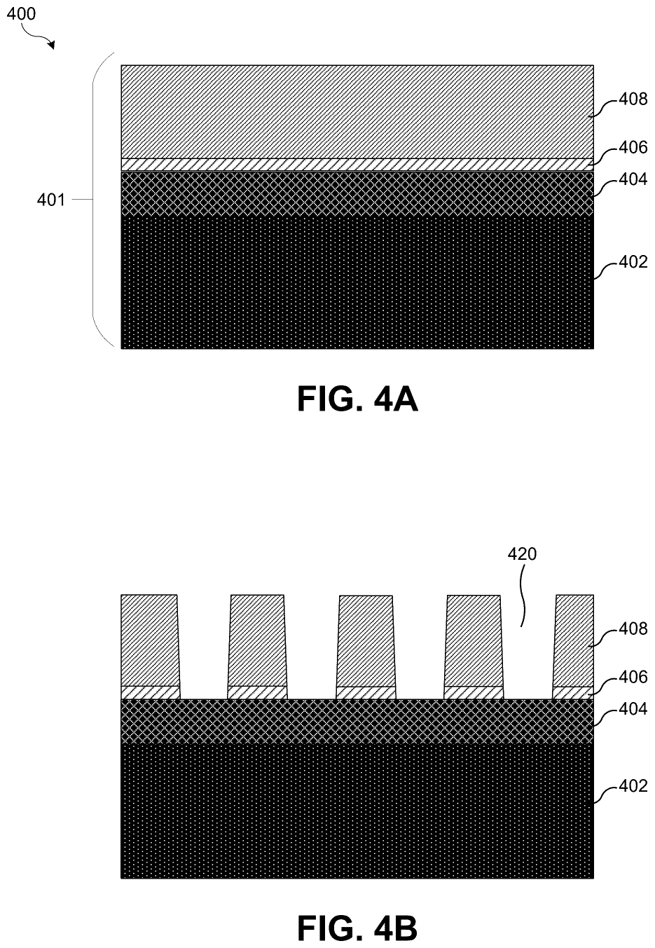

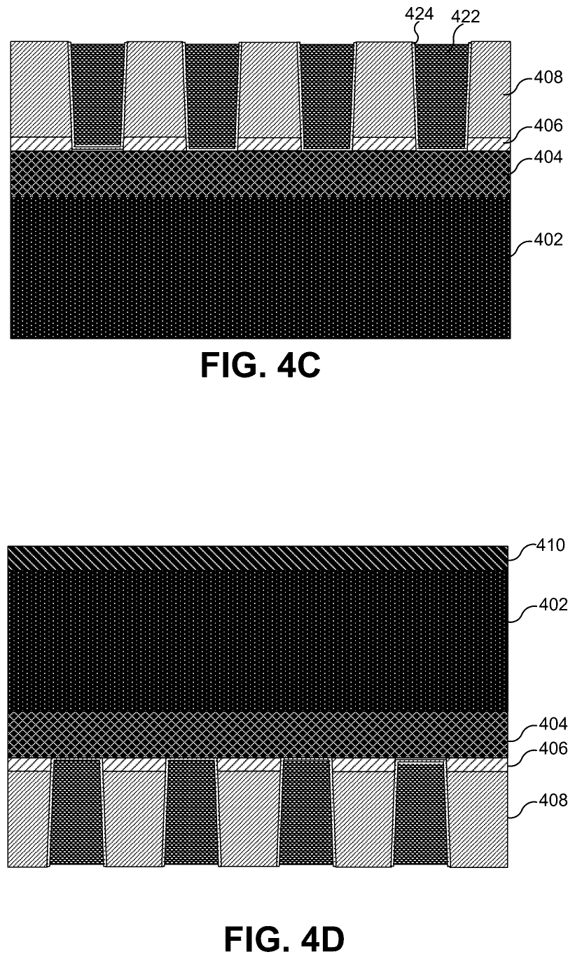

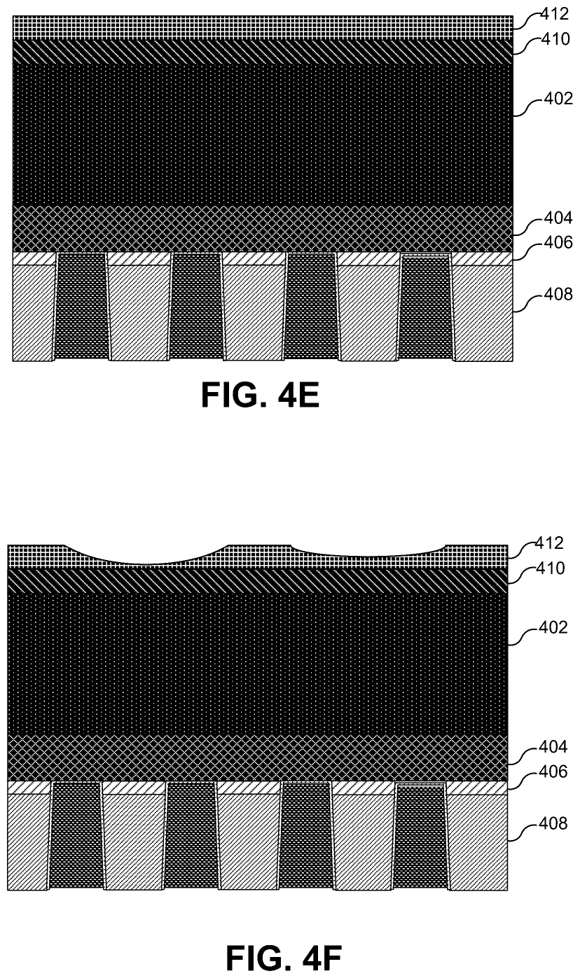

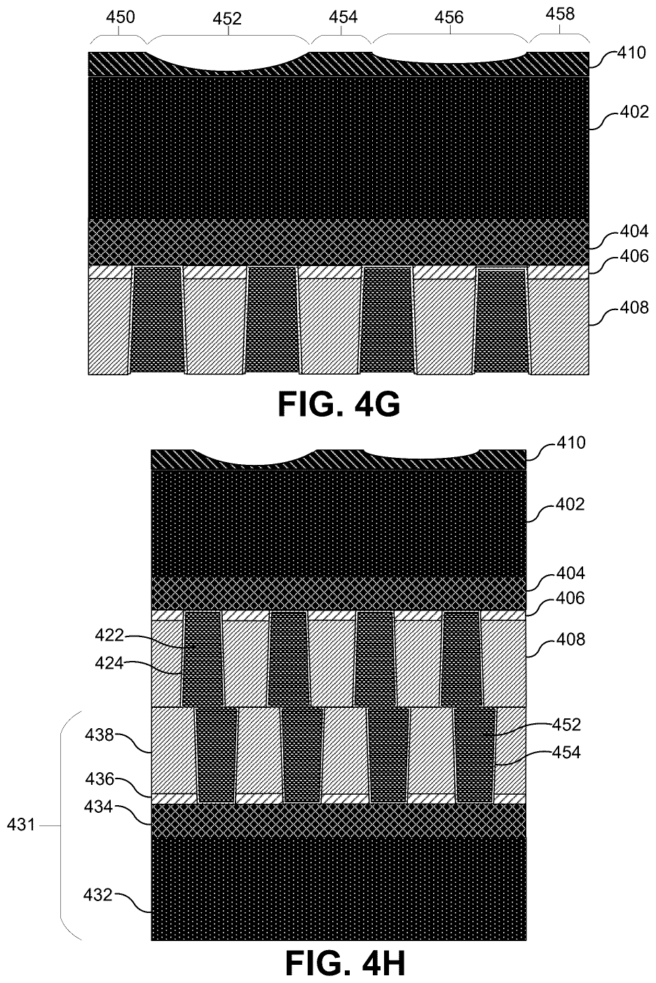

FIG. 3 illustrates a flowchart of exemplary operations in a method 300 of forming a semiconductor structure 400 for hybrid bonding with reduced warpage according to some embodiments of the present technology. The method 300 may be performed in a variety of processing chambers in which the operations may be performed, such as chambers incorporated in the system 100 described above. Method 300 may include one or more operations prior to the initiation of the method 300, including front-end processing, deposition, etching, polishing, cleaning, or any other operations that may be performed prior to the described operations. The methods 300 may include a number of optional operations, which may or may not be specifically associated with some embodiments of methods according to embodiments of the present technology. Method 300 may describe operations shown schematically in FIGS. 4A-4H, the illustrations of which will be described in conjunction with the operations of method 300. It is to be understood that the figures illustrate only partial schematic views, and a semiconductor structure 400 may contain any number of additional materials and features having a variety of characteristics and aspects as illustrated in the figures.

It should be appreciated that the specific steps illustrated in FIG. 3 provide particular methods of forming a semiconductor device 400 for hybrid bonding according to various embodiments. Other sequences of steps may also be performed according to alternative embodiments. For example, alternative embodiments may perform the steps outlined above in a different order. Moreover, the individual steps illustrated in FIG. 3 may include multiple sub-steps that may be performed in various sequences as appropriate to the individual step. Furthermore, additional steps may be added or removed depending on the particular applications. Many variations, modifications, and alternatives also fall within the scope of this disclosure.

FIGS. 4A-4H illustrate incremental structures for forming semiconductor device 400 for hybrid bonding that reduces warpage, according to some embodiments. The method of flowchart 300 describes operations shown schematically in FIGS. 4A-4H, the illustrations of which will be described in conjunction with the operations of this method. It is to be understood that the figures illustrate only partial schematic views with limited details, and in some embodiments a substrate may contain any number of semiconductor sections having aspects as illustrated in the figures, as well as alternative structural aspects that may still benefit from any of the aspects of the present technology. For example, FIGS. 4A-4H will refer to the first structure 401 when describing operations of the method of flowchart 300, but the same operations can be applied to a semiconductor wafer by applying the operations across the semiconductor wafer. The first structure 401 can be an example small section of a semiconductor wafer, and the operations of the method of flowchart 300 can be scaled to encompass an entire semiconductor wafer, chip, or die.

At operation 302, the method of flowchart 300 of reducing warpage in a first structure 401 may include forming a first structure 401. Forming a first structure 401 can include forming a bonding surface that includes both conductive areas and dielectric areas as described below. Specifically, forming a first structure 401 can include forming a metal layer 404 over a substrate 402 and forming a dielectric layer 408 over the metal layer 404. Operation 302 can include forming a metal layer 404 over a substrate 402. As illustrated in FIG. 4A, the structure 400 may include a substrate 402. The substrate 402 may have a substantially planar surface or an uneven surface in various embodiments. The substrate 402 may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. The substrate 426 may have various dimensions, such as 200 mm or 300 mm diameter wafers, as well as substantially rectangular or substantially square panels. The substrate 402 may be disposed within the processing region of the semiconductor processing chamber. Although shown as a planar substrate, it is to be understood that substrate 402 is included merely to represent an underlying structure, which may include any number of layers or features on a wafer or other substrate, and over which structures as described below may be formed.

As illustrated in FIG. 4A, the first structure 401 may include a metal layer 404. The metal layer 404 can include a variety of integrated circuits. For example, the integrated circuits can be created using technologies such as CMOS, NMOS, or any other suitable integrated circuit technology. As such, the metal layer 404 can include various layers of metal, oxide, and semiconductor. Metals used in the metal layer can include copper or any other high conductivity metal. Although this application will regularly discuss copper, it is to be understood that any number of conductive metal materials may be used in embodiments of the present technology, and the present technology should not be limited to any particular conductive metal material.

In some examples, the layers (for example, the substrate 402, the metal layer 404, and other layers described herein such as the barrier film 406, the dielectric layer 408, and the dielectric film 410) described herein can be directly overlaying each other such that the first layer is overlaying the second layer. For example, the metal layer 404 can directly overlay the substrate 402 such that there are no intervening layers. In some examples, the layers described herein can have layers between them. For example, the metal layer 404 can be overlaying an intervening layer which overlays the substrate 402. Furthermore, when forming a layer (for example, the substrate 402, the metal layer 404, the barrier film 406, the dielectric layer 408, or the dielectric film 410), any process for forming or depositing material can be used. For example, chemical vapor deposition (CVD) can be used in some examples while atomic layer deposition (ALD) can be used in other examples. Specifics regarding specific layers and/or materials are also described herein.

Operation 302 can also include forming a dielectric layer 408 over the metal layer 404. As illustrated in FIG. 4A, the dielectric layer 408 may include one or more layers of dielectrics. Example dielectrics can include silicon oxide, tetraethyl orthosilicate (also referred to as TEOS or TeOs), silicon carbon nitride (SiCN), silicon oxynitride (SiON), or any other kind of dielectric. In some examples, the dielectric layer 408 can be TEOS. In some examples, the dielectric layer 408 can be silicon oxide. In some examples, the dielectric layer 408 can be silicon carbon nitride (SiCN). In some examples, the dielectric layer 408 can be silicon oxynitride (SiON). The dielectric layer 408 can also be referred to as the oxide layer.

In some examples, the first structure 401 can include a barrier film 406 between the dielectric layer 408 and the metal layer 404. A barrier film 406 can have a low dielectric constant in order to reduce the dielectric constant of copper damascene structures in order to achieve faster and more powerful devices. Some barrier films can have a dielectric constant of less than 5 or even lower. Example barrier films include silicon nitride films, and low-k barrier films such as BLOK (a Si—C—H compound) or N-BLOK (a Si—C—H—N compound) developed by Applied Materials. The barrier film 406 can also be referred to as a capping layer for the metal layer 404.

At operation 304, the method of flowchart 300 of forming the first structure 401 may include etching and filling a feature in the dielectric layer 408, and the barrier film 406 if applicable. Operation 304 can include etching a feature in the dielectric layer 408. Features etched into the dielectric layer 408 can include trenches, apertures or vias, or any other structure useful in semiconductor processing. As illustrated in FIG. 4B, the structure 400 may include a trench 420 in the dielectric layer 408. In some examples, the trench 420 can extend from a top surface of the dielectric layer 408 down to at least a top surface of the metal layer 404. Although only four features are shown in the figure, it is to be understood that exemplary structures may have any number of features defined along the structure according to embodiments of the present technology.

The etchant used to etch the features into the dielectric layer 408, and if applicable the barrier film 406, can include a variety of semiconductor processing etches that are either solutions or plasmas, such as chlorine, fluorine, oxygen plasma, or fluorine-and-oxygen. In some examples, the etchants can be applied one at a time. In some examples, multiple etchants can be combined to form a multi-material etch. In some examples, a fluorine etch can be used on a TEOS layer of the dielectric layer 408. In some examples, an ashing etch such as an oxygen plasma can be used to remove organics. In some examples, a fluorine-and-oxygen etch can be used on a BLOK or n-BLOK layer of the barrier film 406. In some examples, one or more etches can be dry reactive ion etches. In some examples, one or more etches can be wet etches.

Operation 304 can also include filling the feature with a metal-containing material. As illustrated in FIG. 4C, the structure 400 may include a metal-containing material 422 in the trench 420. The metal-containing material 422 can be a high conductivity material that can be used as an interconnect between integrated circuits. In some examples, the metal in the metal-containing material 422 includes copper such that the metal-containing material 422 is a copper-containing material. Metals used to fill the feature can include copper or any other high conductivity metal. Although this application regularly discusses copper, it is to be understood that any number of conductive metal materials may be used in embodiments of the present technology, and the present technology should not be limited to any particular conductive metal material. The top surface in FIG. 4C may represent a bonding surface with conductive and dielectric areas, while the bottom surface in FIG. 4C may represent a service that is opposite of the bonding surface.

In some examples, a liner is formed in the trench prior to filling the trench with the metal-containing material. As illustrated in FIG. 4C, the structure 400 may include a liner 424 in the trench 420 such that the liner lies in the trench 420 between the dielectric layer 408 and the metal-containing material 422. In some examples, the structure 400 may include a liner 424 in the trench 420 such that the liner lies in the trench 420 between the barrier film 406 and the metal-containing material 422. In some examples, the liner 424 may be tantalum nitride, or any other suitable liner material incorporated to limit or prevent the potential for diffusion of metal into the dielectric material.

In some examples, after the feature has been filled with a metal-containing material 422, the first structure 401 can be polished via a chemical-mechanical polishing (CMP) process. After the first structure 401 has been polished via the CMP process, the top surface of the metal-containing material 422 can be recessed in relation to the top surface of the dielectric layer 408, for example as illustrated in FIG. 4C. The CMP process may cause the top surface of the metal-containing material 422 to form a concave shape or dish shape that may feature a nadir or dish depth, respectively, that is the difference in height between the lowest point in the metal and the surface from which the feature is formed in the dielectric material, or a difference in edge height of the metal within the feature. If the nadir or dish depth combined with a recession depth of the top surface of the metal-containing material 422 to the top surface of the dielectric layer 408 (the combination being referred to as combined depth) is too great, the material may not be useful for certain end products. For example, copper-to-copper hybrid bonding is one such application that may be sensitive to an imprecise combined depth. In some applications of copper-to-copper hybrid bonding, if the combined depth is too great, the copper-to-copper bond may not be sufficiently strong due to limited contact with studs from mating features, or the coupling may not occur at all. A combined depth of less than 5 nm may be small enough for copper-to-copper hybrid bonding, for example.

In some examples, the liner 424 can be polished via the CMP process such that the top surface of the liner 424 aligns with the top surface of the dielectric layer 408. In some examples, the liner 424 can be polished via the CMP process such that the top surface of the liner 424 aligns with the top surface of the metal-containing material 422 as seen in FIG. 4C. In some examples, the liner 424 can be polished via the CMP process such that the top surface of the liner 424 is recessed in relation to the top surface of the dielectric layer 408 and protruding in relation to the top surface of the metal-containing material 422.

At operation 306, the method of flowchart 300 can also include determining locations of warpage in the first structure 401. As described in relation to FIG. 2, a sensor can be used to detect warpage in the first structure 401 and/or the wafer containing the first structure 401. A sensor can be a metrology sensor that can detect pressure, stresses, or displacement of the first structure 401 and/or the wafer. Pressure, stresses, or displacement of the wafer can be indicative of warpage in the first structure 401 and/or the wafer. Using a sensor to detect pressures, stresses, or displacement of the first structure 401 and/or the wafer can be referred to as scanning the first structure 401 and/or the wafer to detect pressures, stresses, or displacement of the wafer.

At operation 308, the method of flowchart 300 can also include determining locations to stress one or more stressed portions of a dielectric film 410 in the first structure 401 to reduce and/or eliminate warpage in the first structure 401. In some examples, determining locations to stress one or more stressed portions of the dielectric film 410 can include etching the dielectric film 410 to reduce and/or eliminate warpage in the first structure 401. In some examples, the determined locations can be referred to as stressed portions of the dielectric film 410. In some examples, the one or more stressed portions of the dielectric film 410 can be directly on top of the local warpage in the first structure 401. In some examples, the one or more stressed portions of the dielectric film 410 can be adjacent to or nearby local warpage in the first structure 401. In some examples, the one or more stressed portions of the dielectric film 410 can be both directly on top of and adjacent to or nearby local warpage in the first structure 401. In some examples, operation 308 can also include determining a material for the dielectric film 410. In some examples, the one or more stressed portions of the dielectric film 410 can refer to portions of the dielectric film 410 that are to be etched. The dielectric film can be comprised of a dielectric material. For example, the dielectric film 410 can include silicon nitride (SiN). Other example dielectric materials for the dielectric film can include silicon oxide, tetraethyl orthosilicate (also referred to as TEOS or TeOs), silicon carbon nitride (SiCN), silicon oxynitride (SiON), or any other kind of dielectric.

In some examples, operation 308 can also include determining sizes for the one or more stressed portions of the dielectric film 410. For example, the width and/or length of the one or more stressed portions can vary based on the width and/or length of the corresponding warped section of the first structure 401. In some examples, operation 308 can include determining a thickness of the dielectric film 410. The dielectric film 410 may be less than or about 10.0 nm, less than or about 9.5 nm, less than or about 9.0 nm, less than or about 8.5 nm, less than or about 8.0 nm, less than or about 7.5 nm, less than or about 7.0 nm, less than or about 6.5 nm, less than or about 6.0 nm, less than or about 5.5 nm, less than or about 5.0 nm, less than or about 4.5 nm, less than or about 4.0 nm, less than or about 3.5 nm, less than or about 3.0 nm, less than or about 2.5 nm, less than or about 2.0 nm, less than or about 1.5 nm, or less than or about 1.0 nm.

At operation 310, the method of flowchart 300 can also include forming a dielectric film 410 over the first structure 401. As shown in FIG. 4D, the dielectric film 410 can be formed over the substrate 402. In some examples, the first structure 401 can be rotated prior to forming the dielectric film 410 over the substrate 402 such that the substrate 402 is upward facing. In other examples, the dielectric film 410 can be formed over the dielectric layer 408 and/or the metal-containing material 422. The dielectric film 410 can be formed according to the locations, sizes, and/or materials that were determined in relation to operation 308.

At operation 312, the method of flowchart 300 can also include etching the dielectric film 410 to reduce warpage in the first structure 401. Etching the dielectric film 410 to reduce warpage in the first structure 401 can be referred to as inducing stress into portions of the dielectric film 410 corresponding to warpage in the first structure 401. For example, the dielectric film 410 can be etched at the locations determined at operation 308. Inducing stress into the stressed portions of the dielectric film 410 can include forming a photoresist layer 412 over the dielectric film 410, applying photolithography to the photoresist layer 412 to form one or more recesses in the photoresist layer 412, and etching the photoresist layer 412 and the dielectric film 410 to form a second set of one or more recesses in the dielectric film 410. Forming the second set of one or more recesses in the dielectric film 410 can create one or more stress zones in the first structure 401 to reduce and/or eliminate warpage in the first structure 401. The one or more recesses can have a variety of shapes as needed. For example, the one or more recesses can form a checkboard pattern or an annulus. Each of the one or more recesses can also have different shapes such as circular, oval, square, rectangular, triangular, or any other shape.

Operation 312 can include forming a photoresist layer 412 over the dielectric film 410. As shown in FIG. 4E, the photoresist layer 412 can be formed over the dielectric film 410. In some examples, the photoresist layer 412 can be spun onto the dielectric film 410. The photoresist layer 412 can be any suitable thickness. In some examples, the photoresist layer 412 may be less than or about 10.0 nm, less than or about 9.5 nm, less than or about 9.0 nm, less than or about 8.5 nm, less than or about 8.0 nm, less than or about 7.5 nm, less than or about 7.0 nm, less than or about 6.5 nm, less than or about 6.0 nm, less than or about 5.5 nm, less than or about 5.0 nm, less than or about 4.5 nm, less than or about 4.0 nm, less than or about 3.5 nm, less than or about 3.0 nm, less than or about 2.5 nm, less than or about 2.0 nm, less than or about 1.5 nm, or less than or about 1.0 nm.

Operation 312 can include applying photolithography to the photoresist layer 412 to form one or more recesses in the photoresist layer 412. In some examples, the photolithography can be greyscale lithography. In some examples, the photolithography can be direct laser grayscale lithography. The photoresist layer 412 can be aligned and exposed to form the one or more recesses in the photoresist layer 412 based on the locations for the one or more recesses determined in relation to operation 308. The photoresist layer 412 can be developed to form the one or more recesses in the photoresist layer 412 based on the locations for the one or more recesses determined in relation to operation 308. As shown in FIG. 4F, one or more recesses have been developed in the photoresist layer 412.

Operation 312 can include etching the photoresist layer 412 and the dielectric film 410 to form a second set of one or more recesses in the dielectric film 410. The photoresist layer 412 and the dielectric film 410 can be exposed to a uniform etchant that etches both the photoresist layer 412 and the dielectric film 410 at approximately the same rate. The universal etchant can be used to etch away the photoresist layer 412 and etch a second set of one or more recesses into the dielectric film 410 that correspond to the one or more recesses in the photoresist layer 412 as seen in FIG. 4F. An example second set of one or more recesses in the dielectric film 410 can be seen in FIG. 4G. The second set of one or more recesses in the dielectric film 410 can be used to create different stress zones in the first structure 401 such as example stress zones 450, 452, 454, 456, and 458. The stress zones 450, 452, 454, 456, and 458 can be vertical portions of the first structure 401. The stress zones 450, 452, 454, 456, and 458 can correspond to the locations for the one or more recesses determined in relation to operation 308. The stress zones 450, 452, 454, 456, and 458 can reduce and/or eliminate warpage in the first structure 401.

In some examples, the method of flowchart 300 can also include forming a semiconductor device by hybrid bonding the first structure 401 with the dielectric film 410 to a second structure 431. In some examples, the method of flowchart 300 may include bonding the first structure 401 to a second structure 431 via hybrid bonding as shown in FIG. 4H. The hybrid process may include bonding the first structure to the second structure, where the bonding surface of the first structure is hybrid bonded to the bonding surface of the second structure, such that the conductive areas of the first structure contacts the second conductive areas of the second structure as shown in the figure. In some examples, the second structure 431 is similar to the first structure 401 in layout, layers, and materials used. The second structure 431 can include a second metal layer 434 overlaying a second substrate 432. The second metal layer 434 can be similar to the metal layer 404 such that all description of the metal layer 404 is applicable to the second metal layer 434. The second substrate 432 can be similar to the substrate 402 such that all description of the substrate 402 is applicable to the second substrate 432. The second structure 431 can also include a second dielectric layer 438 overlaying the second metal layer 434 and defining a second set of one or more features in the second dielectric layer 438. The second dielectric layer 438 of the second structure 431 can be similar to the dielectric layer 408 of the first structure 401 such that all description of the dielectric layer 408 is applicable to the second dielectric layer 438. In some examples, the second structure 431 can include a second barrier film 436 between the second dielectric layer 438 and the second metal layer 434. The second barrier film 436 can be similar to the barrier film 406 such that all description of the barrier film 406 is applicable to the second barrier film 436. The second structure 431 can include a second metal-containing material 454 deposited within the second set of one or more features. The second metal-containing material 454 can be similar to the metal-containing material 422 such that all description of the metal-containing material 422 is applicable to the second metal-containing material 454. In some examples, the material used for the metal-containing material 422 is the same material used for the second metal-containing material 454. In some examples, the second structure 431 may include a second liner 454 in the second set of one or more features such that the second liner 454 lies between the second set of one or more features in the second dielectric layer 438 and the second metal-containing material 454. The second liner 454 can be similar to the liner 424 such that all description of the liner 424 is applicable to the second liner 454. In some examples, the first structure 401 can be considered to be hybrid-bonded to the second structure 431. In some examples, the metal-containing material 422 can be considered hybrid-bonded to the second metal-containing material 454.

The second structure 431 may not include a dielectric film 410. In some examples, the second structure may include a dielectric film overlaying the substrate 432 to reduce and/or eliminate warpage in the second structure 431.

In some examples, bonding the first structure 401 to the second structure 431 can include using a surface activation process on the first structure 401 and/or the second structure 431. The surface activation process can include contacting the first structure 401 and/or the second structure 431 with a hydrogen-containing precursor. The surface activation process can activate the top surface of the dielectric layer 408 of the first structure 401 and/or the top surface of the second dielectric layer 438 of the second structure 431 such that either one or both surfaces have been hydroxylated to have dangling hydroxylation groups. In some examples, water is then applied to the top surface of the dielectric layer 408 of the first structure 401 and/or the second dielectric layer 438 of the second structure 431.

The top surface of the dielectric layer 408 of the first structure 401 and the top surface of the second dielectric layer 438 of the second structure 431 can then be aligned and contacted. When the top surface of the dielectric layer 408 contacts the top surface of the second dielectric layer 438, a spontaneous bonding occurs primarily via Van der Waals bonds to set an initial bond between the top surface of the dielectric layer 408 and the top surface of the second dielectric layer 480. This causes the first structure 401 and the second structure 431 to be bonded together via the top surface of the dielectric layer 408 contacting the top surface of the second dielectric layer. The initial bond between the first structure 401 and the second structure 431 may not be the finalized bond but can be used to keep the first structure 401 and the second structure 431 aligned as additional processes are run to finalize the hybrid bond.

The combination structure of the first structure 401 and the second structure 431 can then annealed. During the annealing operation, the dielectric layer 408 and the second dielectric layer 438 may further form covalent bonds increasing the bond strength between the dielectric layer 408 and the second dielectric layer 438. In some examples, the water and/or the dangling hydroxylation groups assist in forming the covalent bonds between the dielectric layer 408 and the second dielectric layer 438.

The annealing of the combination structure can also cause the metal-containing material 422 to extrude towards the second metal-containing material 454. As previously described, the combined depth of the metal-containing material 422 (and the second metal-containing material 454 by extension) is important for the bonding of the metal-containing materials. When the combined depth is less than 5 nm or lower, subsequent annealing to bond the metal-containing material 422 and the second metal-containing material 454 may be effective as the metal-containing material 422 and the second metal-containing material 454 may be close enough to bond to each other during the annealing step of hybrid bonding. As described herein, warpage in one or both of the first structure 401 and the second structure 431 can cause the metal-containing material 422 and the second metal-containing material 454 to be too far apart for at least some interconnects between the first structure 401 and the second structure 431. During the annealing step, the metal-containing materials from the two structures may extrude towards one another, may contact each other, and may bond. At reduced annealing temperatures according to some embodiments of the present technology, unless the dishing is sufficiently reduced, the amount of expansion may be insufficient to allow adequate coupling between the copper. By performing polishing operations according to the present technology, reduce dishing may be provided, which may improve coupling capability between substrates at reduced annealing temperatures.

Once the annealing process is completed, the first structure 401 and the second structure 431 are hybrid bonded to form a single semiconductor device or a single structure. The use of hybrid bonding enables the fabrication of complex semiconductor devices from multiple structures and form the interconnects between the structures.

Once the annealing process is completed, the dielectric film 410 can be removed from the first structure 401. The dielectric film 410 can be removed by use of a selective etch that primarily etches the dielectric film rather than the substrate 402, the metal layer 404, and/or the dielectric layer 408 and the analogous layers of the second structure 431.

In some examples, operation 304 of etching and filling features in the dielectric layer 408 of the first structure 401 can occur after operations 306, 308, 310, and 312. For example, etching and filling features in the dielectric layer 408 can be occur after determining locations of warpage in the first structure 401, determining locations to stress one or more stressed portions of the dielectric film 410, forming the dielectric film 410 over the first structure 401, and inducing stressed into the stressed portions of the dielectric film 410. In some examples, etching and filling the features in the dielectric layer 408 after operations 306, 308, 310, and 312 can be beneficial in simplifying the warpage reduction process. In some examples, etching and filling the features in the dielectric layer 408 before operations 306, 308. 310, and 312 as described in relation to FIGS. 3 and 4A-4H can be beneficial because the warpage present in the first structure 401 can change after etching and filling the features in the dielectric layer 408.

In some examples, the dielectric film 410 can be removed prior to hybrid bonding the first structure 401 to the second structure 431. In such examples, the dielectric film 410 can be formed on the first structure 401 and overlay the first structure 401 for a duration. The duration can be any length of time. While the dielectric film 410 overlays the first structure, the one or more stressed portions of the dielectric film 410 can reduce and/or eliminate warpage. In some examples, the reduced and/or eliminated warpage can remain reduced and/or eliminated once the dielectric film is removed.

In some examples, operation 308 can include determining that the dielectric film 410 can be formed over the dielectric layer 408 rather than over the substrate 402 as described in relation to FIGS. 3 and 4A-4H. In such examples, operation 310 can include forming the dielectric film 410 over the dielectric layer 408. When forming the dielectric film 410 over the dielectric layer 408, the dielectric film 410 can be removed prior to hybrid bonding the first structure 401 to the second structure 431.

In some examples, the second structure 431 can have a second dielectric film formed over the second structure 431. All description of the dielectric film 410 regarding the composition and formation of the dielectric film 410 can apply to the second dielectric film formed over the second structure 431.

Any combination of the above additional example steps of process 300 can be combined. For example, the dielectric film 410 can be formed over the dielectric layer 408 and removed prior to hybrid-bonding the first structure 401 and the second structure 431. Likewise, operation 304 of etching and filling features in the dielectric layer 408 can occur after operations 306, 308, 310, and 312 and the dielectric film 410 can be removed prior to hybrid-bonding the first structure 401 and the second structure 431.

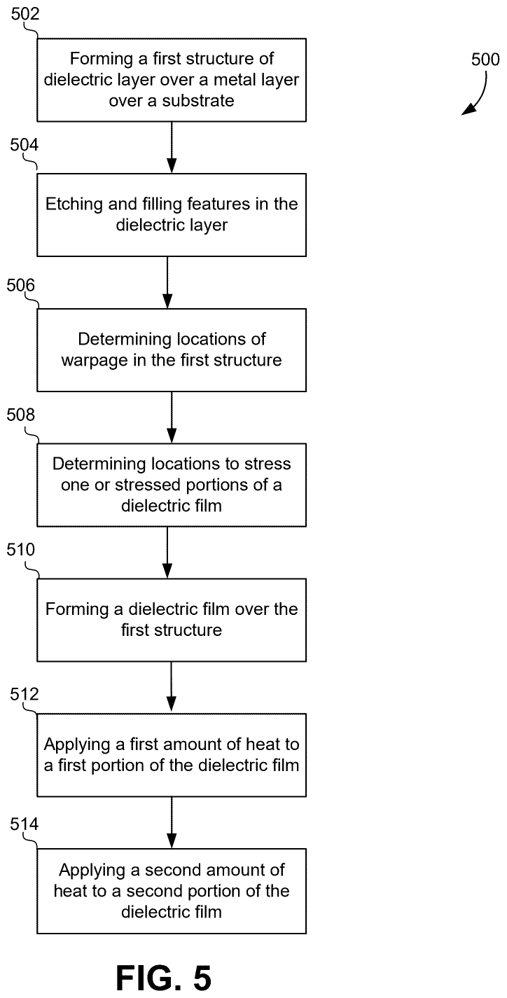

FIG. 5 illustrates a flowchart of exemplary operations in a method 500 of forming a

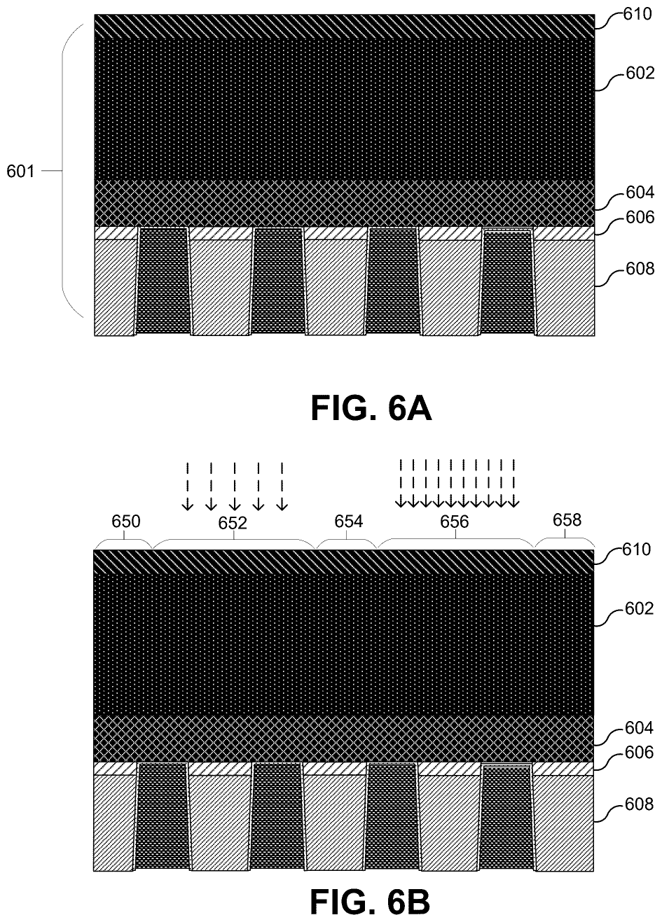

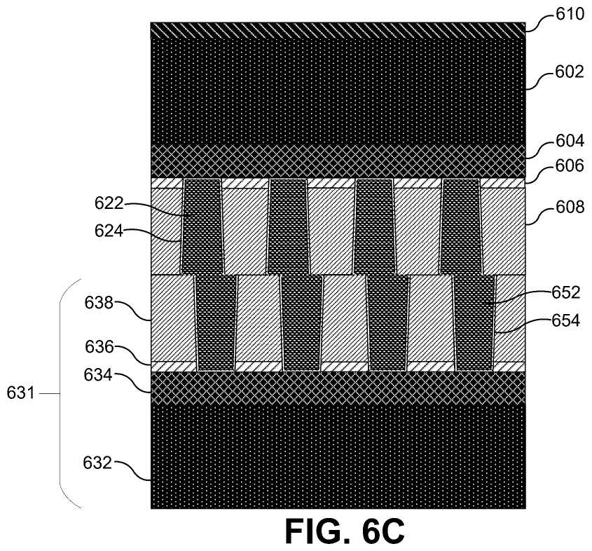

semiconductor structure 600 for hybrid bonding with reduced warpage according to some embodiments of the present technology. The method 500 may be performed in a variety of processing chambers in which the operations may be performed, such as chambers incorporated in the system 100 described above. Method 500 may include one or more operations prior to the initiation of the method 500, including front-end processing, deposition, etching, polishing, cleaning, or any other operations that may be performed prior to the described operations. The methods 500 may include a number of optional operations, which may or may not be specifically associated with some embodiments of methods according to embodiments of the present technology. Method 500 may describe operations shown schematically in FIGS. 4A-4C and 6A-6C, the illustrations of which will be described in conjunction with the operations of method 500. It is to be understood that the figures illustrate only partial schematic views, and a semiconductor structure 600 may contain any number of additional materials and features having a variety of characteristics and aspects as illustrated in the figures.

It should be appreciated that the specific steps illustrated in FIG. 5 provide particular methods of forming a semiconductor device 600 for hybrid bonding according to various embodiments. Other sequences of steps may also be performed according to alternative embodiments. For example, alternative embodiments may perform the steps outlined above in a different order. Moreover, the individual steps illustrated in FIG. 5 may include multiple sub-steps that may be performed in various sequences as appropriate to the individual step. Furthermore, additional steps may be added or removed depending on the particular applications. Many variations, modifications, and alternatives also fall within the scope of this disclosure.

At operation 502, the method of flowchart 500 of reducing warpage in a first structure 601 may include forming a first structure 601. Operation 502 can be similar to operation 302 of FIG. 3. The description of operation 302 herein can apply to operation 502. FIG. 4A can be used illustrate parts of operation 502. The first structure 601, the substrate 602, the metal layer 604, the barrier film 606, and the dielectric layer 608 of FIGS. 6A-6C can correspond to the first structure 401, the substrate 402, the metal layer 404, the barrier film 406, and the dielectric layer 408 of FIGS. 4A-4C. The description of the first structure 401, the substrate 402, the metal layer 404, the barrier film 406, and the dielectric layer 408 of FIGS. 4A-4C can apply to the first structure 601, the substrate 602, the metal layer 604, the barrier film 606, and the dielectric layer 608 of FIGS. 6A-6C.

At operation 504, the method of flowchart 500 of forming the first structure 601 may include etching and filling a feature in the dielectric layer 608, and the barrier film 606 if applicable. Operation 504 can be similar to operation 304 of FIG. 3. The description of operation 304 herein can apply to operation 504. FIG. 4B-4C can be used illustrate parts of operation 504. The metal-containing material 622 and the liner 624 of FIGS. 6A-6C can correspond to metal-containing material 422 and the liner 424 of FIGS. 4B-4C. The description of the metal-containing material 422 and the liner 424 of FIGS. 4B-4C can apply to the metal-containing material 622 and the liner of FIGS. 6A-6C.

At operation 506, the method of flowchart 500 can also include determining locations of warpage in the first structure 601. These operations may obtain data for the semiconductor structure that is indicative of warpage locations; and cause stress to be induced into one or more portions of a film on the semiconductor structure to create one or more stressed portions that compensate for the warpage locations. As described in relation to FIG. 2, a sensor can be used to detect warpage in the first structure 601 and/or the wafer containing the first structure 601. A sensor can be a metrology sensor that can detect pressure, stresses, or displacement of the first structure 601 and/or the wafer. Pressure, stresses, or displacement of the wafer can be indicative of warpage in the first structure 601 and/or the wafer. Using a sensor to detect pressures, stresses, or displacement of the first structure 601 and/or the wafer can be referred to as scanning the first structure 601 and/or the wafer to detect pressures, stresses, or displacement of the wafer.

At operation 508, the method of flowchart 500 can also include determining locations to stress one or more stressed portions of a dielectric film 610 in the first structure 601 to reduce and/or eliminate warpage in the first structure 601. The method of flowchart 500 relates to the heating of portions of the dielectric film 610 in order to stress (and thus form) the one or more stressed portions of the dielectric film 610. As such, the locations that are determined here in operation 508 may be different than the locations determined in operation 308 due to differences in the stressing process of the dielectric film 610. In some examples, the one or more stressed portions of the dielectric film 610 can be directly on top of the local warpage in the first structure 601. In some examples, the one or more stressed portions of the dielectric film 610 can be adjacent to or nearby local warpage in the first structure 601. In some examples, the one or more stressed portions of the dielectric film 610 can be both directly on top of and adjacent to or nearby local warpage in the first structure 401. In some examples, operation 508 can also include determining a material for the dielectric film 610. The dielectric film can be comprised of a dielectric material. For example, the dielectric film 610 can include silicon nitride (SiN). Other example dielectric materials for the dielectric film can include silicon oxide, tetraethyl orthosilicate (also referred to as TEOS or TeOs), silicon carbon nitride (SiCN), silicon oxynitride (SiON), silicon oxycarbide (SiOC), or any other kind of dielectric. In some examples, the dielectric film 610 can be a high aspect ratio process (HARP) stressed film. In some examples, the dielectric film 610 can be composed of at least silicon oxycarbide.

At operation 510, the method of flowchart 500 can also include forming a dielectric film 610 over the first structure 601. As shown in FIG. 6A, the dielectric film 610 can be formed over the substrate 602. In some examples, the first structure 601 can be rotated prior to forming the dielectric film 610 over the substrate 602 such that the substrate 602 is upward facing. In other examples, the dielectric film 610 can be formed over the dielectric layer 608 and/or the metal-containing material 622. The dielectric film 610 can be formed according to the locations, sizes, and/or materials that were determined in relation to operation 508.

At operation 512, the method of flowchart 500 can include applying a first amount of heat to a first portion of the dielectric film 610. As illustrated in FIG. 6B, a first amount of heat can be applied to the first portion 652 of the dielectric film 610 as indicated by the dashed arrows. The first amount of heat can be applied to the first portion 652 of the dielectric film via heating lamps in the semiconductor processing chamber or via a laser. A laser can be used to precisely control where heat is applied in the dielectric film 610 and can also be precise in the amount of heat applied. By applying the first amount of heat to the first portion 652, stress zones can be created in the first structure 601. For example, stress zones 650 and 654 can be created by applying the first amount of heat to the first portion 652. Similarly, a stress zone corresponding to the first portion 652 can be created by applying the first amount of heat to the first portion 652. The stress zones 650 and 654 and the stress zone corresponding to the first portion 652 be vertical portions of the first structure 601. The stress zones 650 and 654 and the stress zone corresponding to the first portion 652 can reduce and/or eliminate warpage in the first structure 601.

At operation 514, the method of flowchart 500 can include applying a second amount of heat to a second portion of the dielectric film 610. As illustrated in FIG. 6B, a second amount of heat can be applied to the second portion 656 of the dielectric film 610 as indicated by the dashed arrows. The second amount of heat can be applied to the second portion 652 of the dielectric film via heating lamps in the semiconductor processing chamber or via a laser. In FIG. 6B, the second amount of heat can be greater than the first amount of heat as shown by a larger density of dashed arrows. By applying the second amount of heat to the second portion 656, stress zones can be created in the first structure 601. For example, stress zones 658 can be created by applying the second amount of heat to the second portion 656. Similarly, a stress zone corresponding to the second portion 656 can be created by applying the second amount of heat to the second portion 656. Additionally, the stress zone 654 can be affected by the second amount of heat being applied to the second portion 652. The effect of applying the second amount of heat to the second portion 652 can be accounted for during operation 508 when determining locations to stress one or more stressed portions of a dielectric film 610. The stress zone 658 and the stress zone corresponding to the second portion 656 be vertical portions of the first structure 601. The stress zones 658 and the stress zone corresponding to the second portion 658 can reduce and/or eliminate warpage in the first structure 601.

In some examples, the method of flowchart 500 can also include forming a semiconductor device by hybrid bonding the first structure 601 with the dielectric film 610 to a second structure 631. In some examples, the method of flowchart 500 may include bonding the first structure 601 to a second structure 631 via hybrid bonding as shown in FIG. 6C. In some examples, the second structure 631 is similar to the first structure 601 in layout, layers, and materials used. The second structure 631 can include a second metal layer 634 overlaying a second substrate 632. The second metal layer 634 can be similar to the metal layer 604 such that all description of the metal layer 604 is applicable to the second metal layer 634. The second substrate 632 can be similar to the substrate 602 such that all description of the substrate 602 is applicable to the second substrate 632. The second structure 631 can also include a second dielectric layer 638 overlaying the second metal layer 634 and defining a second set of one or more features in the second dielectric layer 638. The second dielectric layer 638 of the second structure 631 can be similar to the dielectric layer 608 of the first structure 601 such that all description of the dielectric layer 608 is applicable to the second dielectric layer 638. In some examples, the second structure 631 can include a second barrier film 636 between the second dielectric layer 638 and the second metal layer 634. The second barrier film 636 can be similar to the barrier film 606 such that all description of the barrier film 606 is applicable to the second barrier film 636. The second structure 631 can include a second metal-containing material 654 deposited within the second set of one or more features. The second metal-containing material 654 can be similar to the metal-containing material 622 such that all description of the metal-containing material 622 is applicable to the second metal-containing material 654. In some examples, the material used for the metal-containing material 622 is the same material used for the second metal-containing material 654. In some examples, the second structure 631 may include a second liner 654 in the second set of one or more features such that the second liner 654 lies between the second set of one or more features in the second dielectric layer 638 and the second metal-containing material 654. The second liner 654 can be similar to the liner 624 such that all description of the liner 624 is applicable to the second liner 654. In some examples, the first structure 601 can be considered to be hybrid-bonded to the second structure 631. In some examples, the metal-containing material 622 can be considered hybrid-bonded to the second metal-containing material 654.

The second structure 631 may not include a dielectric film 610. In some examples, the second structure may include a dielectric film overlaying the substrate 632 to reduce and/or eliminate warpage in the second structure 631.

Hybrid bonding the first structure 601 and the second structure 631 can be analogous to hybrid bonding the first structure 401 and the second structure 431 as described in relation to FIG. 4H. All description of hybrid bonding the first structure 401 and the second structure 431 can be applied to hybrid bonding the first structure 601 and the second structure 631.

In some examples, operation 504 of etching and filling features in the dielectric layer 608 of the first structure 601 can occur after operations 506, 508, 510, 512, and 514. For example, etching and filling features in the dielectric layer 608 can be occur after determining locations of warpage in the first structure 601, determining locations to stress one or more stressed portions of the dielectric film 610, forming the dielectric film 610 over the first structure 601, applying a first amount of heat to the first portion 652 of the dielectric film 610, and applying a second amount of heat to the second portion 656 of the dielectric film 610. In some examples, etching and filling the features in the dielectric layer 608 after operations 506, 508, 510, 512, and 514 can be beneficial in simplifying the warpage reduction process. In some examples, etching and filling the features in the dielectric layer 608 before operations 506, 508. 510, 512, and 514 as described in relation to FIGS. 4A-4C, 5, and 6A-6C can be beneficial because the warpage present in the first structure 601 can change after etching and filling the features in the dielectric layer 608.

In some examples, the dielectric film 610 can be removed prior to hybrid bonding the first structure 601 to the second structure 631. In such examples, the dielectric film 610 can be formed on the first structure 601 and overlay the first structure 601 for a duration. The duration can be any length of time. While the dielectric film 610 overlays the first structure, the one or more stressed portions of the dielectric film 610 can reduce and/or eliminate warpage. In some examples, the reduced and/or eliminated warpage can remain reduced and/or eliminated once the dielectric film is removed.

In some examples, operation 508 can include determining that the dielectric film 610 can be formed over the dielectric layer 608 rather than over the substrate 602 as described in relation to FIGS. 5 and 6A-6C. In such examples, operation 510 can include forming the dielectric film 610 over the dielectric layer 608. When forming the dielectric film 610 over the dielectric layer 608, the dielectric film 610 can be removed prior to hybrid bonding the first structure 601 to the second structure 631.

In some examples, the second structure 631 can have a second dielectric film formed over the second structure 631. All description of the dielectric film 610 regarding the composition and formation of the dielectric film 610 can apply to the second dielectric film formed over the second structure 631.

Any combination of the above additional example steps of method 500 can be combined. For example, the dielectric film 610 can be formed over the dielectric layer 608 and removed prior to hybrid-bonding the first structure 601 and the second structure 631. Likewise, operation 504 of etching and filling features in the dielectric layer 608 can occur after operations 306, 308, 310, 312, and 314 and the dielectric film 610 can be removed prior to hybrid-bonding the first structure 601 and the second structure 631.

Additionally, a dielectric film overlaying a first structure can be stressed as described in relation to FIGS. 3 and 4A-4H while a dielectric film (either the same dielectric film, or a second dielectric film) overlaying a second structure can be stressed as described in relation to FIGS. 5 and 6A-6C. For example, the dielectric film overlaying a first structure of a first wafer can be stressed as described in relation to FIGS. 3 and 4A-4H to reduce and/or eliminate warpage in the first structure of the first wafer. Similarly, the same dielectric film can overlay a second structure of the first wafer. The dielectric film overlaying the second structure of the first wafer can be as described in relation to FIGS. 5 and 6A-6C to reduce and/or eliminate warpage in the second structure of the first wafer. Alternatively, the dielectric film overlaying a first structure of a first wafer can be stressed as described in relation to FIGS. 3 and 4A-4H to reduce and/or eliminate warpage in the first structure of the first wafer. A second dielectric film can overlay a second structure of a second wafer. The second dielectric film overlaying the second structure of the second wafer can be as described in relation to FIGS. 5 and 6A-6C to reduce and/or eliminate warpage in the second structure of the second wafer. The first wafer and the second wafer can be hybrid bonded together such that the first structure is hybrid bonded to the second structure.

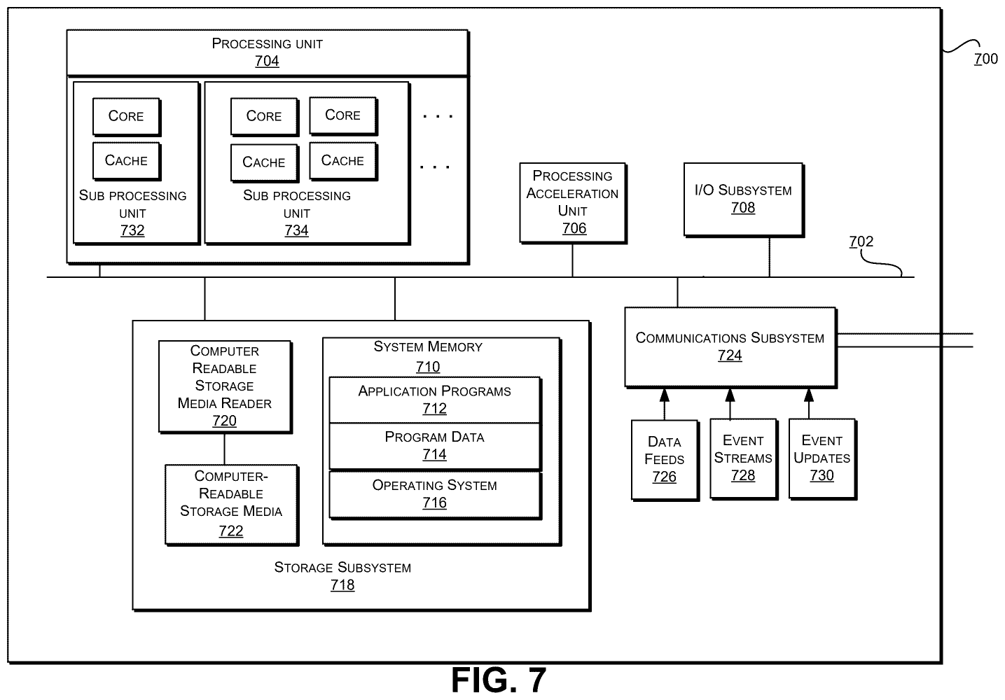

FIG. 7 illustrates an exemplary computer system 700, in which various embodiments may be implemented. The system 700 may be used to implement any of the computer systems described above. As shown in the figure, computer system 700 includes a processing unit 704 that communicates with a number of peripheral subsystems via a bus subsystem 702. These peripheral subsystems may include a processing acceleration unit 706, an I/O subsystem 708, a storage subsystem 718 and a communications subsystem 724. Storage subsystem 718 includes tangible computer-readable storage media 722 and a system memory 710.

Bus subsystem 702 provides a mechanism for letting the various components and subsystems of computer system 700 communicate with each other as intended. Although bus subsystem 702 is shown schematically as a single bus, alternative embodiments of the bus subsystem may utilize multiple buses. Bus subsystem 702 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 704, which can be implemented as one or more integrated circuits (e.g., a conventional microprocessor or microcontroller), controls the operation of computer system 700. One or more processors may be included in processing unit 704. These processors may include single core or multicore processors. In certain embodiments, processing unit 704 may be implemented as one or more independent processing units 732 and/or 734 with single or multicore processors included in each processing unit. In other embodiments, processing unit 704 may also be implemented as a quad-core processing unit formed by integrating two dual-core processors into a single chip.

In various embodiments, processing unit 704 can execute a variety of programs in response to program code and can maintain multiple concurrently executing programs or processes. At any given time, some or all of the program code to be executed can be resident in processor(s) 704 and/or in storage subsystem 718. Through suitable programming, processor(s) 704 can provide various functionalities described above. Computer system 700 may additionally include a processing acceleration unit 706, which can include a digital signal processor (DSP), a special-purpose processor, and/or the like.

I/O subsystem 708 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 700 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 700 may comprise a storage subsystem 718 that comprises software elements, shown as being currently located within a system memory 710. System memory 710 may store program instructions that are loadable and executable on processing unit 704, as well as data generated during the execution of these programs.

Depending on the configuration and type of computer system 700, system memory 710 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 704. In some implementations, system memory 710 may include multiple different types of memory, such as static random access memory (SRAM) or dynamic random access memory (DRAM). In some implementations, a basic input/output system (BIOS), containing the basic routines that help to transfer information between elements within computer system 700, such as during start-up, may typically be stored in the ROM. By way of example, and not limitation, system memory 710 also illustrates application programs 712, which may include client applications, Web browsers, mid-tier applications, relational database management systems (RDBMS), etc., program data 714, and an operating system 716. By way of example, operating system 716 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 718 may also provide a tangible computer-readable storage medium for storing the basic programming and data constructs that provide the functionality of some embodiments. Software (programs, code modules, instructions) that when executed by a processor provide the functionality described above may be stored in storage subsystem 718. These software modules or instructions may be executed by processing unit 704. Storage subsystem 718 may also provide a repository for storing data used in accordance with some embodiments.

Storage subsystem 700 may also include a computer-readable storage media reader 720 that can further be connected to computer-readable storage media 722. Together and, optionally, in combination with system memory 710, computer-readable storage media 722 may comprehensively represent remote, local, fixed, and/or removable storage devices plus storage media for temporarily and/or more permanently containing, storing, transmitting, and retrieving computer-readable information.

Computer-readable storage media 722 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 700.

By way of example, computer-readable storage media 722 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 722 may include, but is not limited to, Zip® drives, flash memory cards, universal serial bus (USB) flash drives, secure digital (SD) cards, DVD disks, digital video tape, and the like. Computer-readable storage media 722 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 700.

Communications subsystem 724 provides an interface to other computer systems and networks. Communications subsystem 724 serves as an interface for receiving data from and transmitting data to other systems from computer system 700. For example, communications subsystem 724 may enable computer system 700 to connect to one or more devices via the Internet. In some embodiments communications subsystem 724 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 724 can provide wired network connectivity (e.g., Ethernet) in addition to or instead of a wireless interface.

In some embodiments, communications subsystem 724 may also receive input communication in the form of structured and/or unstructured data feeds 726, event streams 728, event updates 730, and the like on behalf of one or more users who may use computer system 700.

Additionally, communications subsystem 724 may also be configured to receive data in the form of continuous data streams, which may include event streams 728 of real-time events and/or event updates 730, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 724 may also be configured to output the structured and/or unstructured data feeds 726, event streams 728, event updates 730, and the like to one or more databases that may be in communication with one or more streaming data source computers coupled to computer system 700.

Computer system 700 can be one of various types, including a handheld portable device (e.g., an iPhone® cellular phone, an iPad® computing tablet, a PDA), a wearable device (e.g., a Google Glass® head mounted display), a PC, a workstation, a mainframe, a kiosk, a server rack, or any other data processing system.

Due to the ever-changing nature of computers and networks, the description of computer system 700 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMS, EEPROMs, magnetic or optical cards, flash memory, or other types of machine-readable mediums suitable for storing electronic instructions. Alternatively, the methods may be performed by a combination of hardware and software.

What is claimed is:

1. A semiconductor structure for hybrid bonding, the semiconductor structure comprising:
a first structure comprising a bonding surface and a surface opposite of the bonding surface, wherein the bonding surface comprises conductive areas and dielectric areas; and
a film overlaying the first structure on the surface of the first structure that is opposite of the bonding surface, wherein the film comprises one or more stressed portions that compensate for warpage in the first structure.

2. The semiconductor structure of claim 1, wherein the first structure further comprises:
a metal layer;
a dielectric layer overlaying the metal layer and defining one or more features recessed in the dielectric layer; and
a copper-containing material within the one or more features and forming one or more connections to the metal layer.

3. The semiconductor structure of claim 1, wherein the one or more stressed portions include one or more recesses in the film.

4. The semiconductor structure of claim 1, wherein the one or more stressed portions include a first portion exposed to a first amount of heat creating a first stress zone in the first structure, and a second portion exposed to a second amount of heat different than the first amount of heat, and wherein the first portion and the second portion correspond to a first location and second location, respectively, of warpage in the first structure.

5. The semiconductor structure of claim 1, further comprising a second structure, wherein the second structure comprises a second bonding surface, and the second bonding surface comprises second conductive areas and second dielectric areas;
wherein the bonding surface of the first structure is hybrid bonded to the second bonding surface of the second structure, wherein the conductive areas of the first structure contact the second conductive areas of the second structure.

6. A method of forming a semiconductor structure, the method comprising:
forming a first structure comprising a bonding surface and a surface opposite of the bonding surface, wherein the bonding surface comprises conductive areas and dielectric areas; and
forming a film overlaying the first structure on the surface of the first structure that is opposite of the bonding surface, wherein the film comprises one or more stressed portions that compensate for warpage in the first structure.

7. The method of claim 6, further comprising:
forming a photoresist layer over the film;
determining areas for each of one or more recesses to place in the stressed portions of the film;
applying photolithography to the photoresist layer based on the areas for each of the one or more recesses to form a second set of one or more recesses in the photoresist layer, wherein the second set of one or more recesses corresponds to the one or more recesses; and
applying an etchant to the photoresist layer and the film to form the one or more recesses in the film.

8. The method of claim 6, further comprising:
applying a first amount of heat to a first portion of the film to form a first stress zone in the first structure; and
applying a second amount of heat to a second portion of the film, wherein the first amount of heat is different from the second amount of heat to form a second stress zone in the first structure, and the first portion and the second portion correspond to a first location and second location, respectively, of warpage in the first structure.

9. The method of claim 8, wherein a laser is used to apply the first amount of heat and the second amount of heat.

10. The method of claim 6, further comprising removing the film from the first structure.

11. The method of claim 6, further comprising:
contacting the first structure with a second structure formed in a wafer, the second structure comprising a second bonding surface, and the second bonding surface comprising second conductive areas and second dielectric areas; and
bonding the first structure to the second structure, wherein the bonding surface of the first structure is hybrid bonded to the bonding surface of the second structure, such that the conductive areas of the first structure contacts the second conductive areas of the second structure.

12. The method of claim 6, further comprising:
contacting the first structure with a second structure formed in a die, the second structure comprising a second bonding surface, and the second bonding surface comprising second conductive areas and second dielectric areas; and
bonding the first structure to the second structure, wherein the bonding surface of the first structure is hybrid bonded to the bonding surface of the second structure, such that the conductive areas of the first structure contacts the second conductive areas of the second structure.

13. The method of claim 12, further comprising removing the film from the first structure after bonding the first structure to the second structure.

14. A method comprising:
obtaining data for a semiconductor structure that is indicative of warpage locations; and
causing stress to be induced into one or more portions of a film on the semiconductor structure to create one or more stressed portions that compensate for the warpage locations.

15. The method of claim 14, further comprising:
determining first locations of warpage in the semiconductor structure by performing a metrology test on the semiconductor structure; and
determining second locations to induce stress into one or more stressed portions of a dielectric film overlaying the semiconductor structure to create one or more stress zones in the semiconductor structure, wherein the one or more stress zones correspond to the first locations of warpage.

16. The method of claim 14, further comprising determining one or more sizes and one or more shapes for the one or more stressed portions.

17. The method of claim 14, further comprising determining a material for the film.

18. The method of claim 14, further comprising determining a film thickness for the film.

19. The method of claim 14, wherein the film thickness is between about 1 nm and about 10 nm.

20. The method of claim 14, wherein the film material comprises a dielectric material.
